(19) United States
(12) Patent Application Publication
(10) Pub. No.: US 2024/0351050 A1
(43) Pub. Date: Oct. 24, 2024

(54) MATERIAL SEPARATION IN SOLAR MODULE RECYCLING

(71) Applicant: SOLARCYCLE, Inc., Odessa, TX (US)

(72) Inventor: Pablo RIBEIRO DIAS, Oakland, CA (US)

(21) Appl. No.: 18/643,546

(22) Filed: Apr. 23, 2024

Related U.S. Application Data
(60) Provisional application No. 63/497,823, filed on Apr. 24, 2023.

(51) Int. Cl. B03C 7/00; B03B 9/06; B09B 3/35; B09B 101/15; H02S 99/00

(52) U.S. Cl. CPC B03C 7/003; B03B 9/06; B09B 3/35; H02S 99/00; B09B 2101/15

(57) ABSTRACT

Separation of materials for recycling of a used solar module, may be accomplished through the application of an electric field. The solar module may be processed utilizing one or more of grinding, shaking, drying, sieving, slicing, electrodynamic separation, glass removal cutting, shaving, shredding, application of fluid jet(s), blasting, application of ultrasound, application of radiation, and/or application of solvents. According to particular embodiments, it may be desirable to run electrostatic separation of materials without the presence of glass, in particular without the presence of small glass particles. For example, if around >90 wt % of original glass is removed, a separation process can proceed with higher effectiveness.

### CROSS-REFERENCE TO RELATED APPLICATION

The instant nonprovisional patent application claims priority to U.S. Provisional Patent Application No. 63/497,823, filed Apr. 24, 2023 and incorporated by reference in its entirety herein.

### BACKGROUND

As world population increases, the earth is subjected to escalating environmental stress. One form of stress is manifest in rising global temperatures attributable to the burning of fossil fuels in order to provide energy needs.

Alternative energy sources can provide power, while lessening the carbon dioxide burden on the planet. One important source of alternative energy is solar power.

Solar modules are complex manufactured items. They harness the sun's energy and convert it into a usable energy source for residential, commercial and utility-scale applications. As the climate has been significantly impacted by the use of fossil fuels over the past century, the need for alternative sources of energy like solar has taken on greater importance.

Another form of environmental stress imposed upon the earth, is the accumulation and disposal of waste products from human activity. Accordingly, rather than discarding a solar module at the end of its lifetime, it may be desirable to recycle material(s) from a solar module for reuse and thereby avoid deposition in a landfill.

### SUMMARY

Separation of materials for recycling of a used solar module, may be accomplished through the application of an electric field. The solar module may be processed utilizing one or more of grinding, shaking, drying, sieving, slicing, electrodynamic separation, glass removal cutting, shaving, shredding, application of fluid jet(s), blasting, application of ultrasound, application of radiation, and/or application of solvents. According to particular embodiments, it may be desirable to run electrostatic separation of materials without the presence of glass, in particular without the presence of small glass particles. For example, if around >90 wt % of original glass is removed, a separation process can proceed with higher effectiveness.

### BRIEF DESCRIPTION OF THE DRAWINGS

FIG. 1 shows a simplified cross-section of a solar module.

FIG. 1A shows a simplified plan view of a solar module.

FIG. 2 shows a simplified view of an embodiment of a separation apparatus.

FIG. 3 shows a simplified view of one specific implementation of materials separation according to a particular embodiment.

FIG. 4 shows a particular embodiment utilizing a grounded roller and internal positioning electrodes.

FIG. 5 shows a simplified flow diagram of processing of a used solar module for recycling, according to an embodiment.

### DESCRIPTION

Solar modules exist in a variety of types and architectures. Examples of such modules can include but are not limited to:
Monocrystalline Solar Panels (Mono-SI)
Polycrystalline Solar Panels (p-Si)
Amorphous Silicon Solar Panels (A-SI)
Cadmium telluride photovoltaics (CdTe)
Copper indium gallium selenide modules (CIGS)
Copper indium selenide modules (CIS)
Concentrated PV Cell (CVP)
Biohybrid Solar modules
Monofacial modules
Bifacial modules
Modules without encapsulant
Silicon heterojunction solar modules
tunnel oxide passivated contact solar modules (TOPCON)
passivated emitter and rear contact solar modules (PERC)
Tandem-junction Solar Panels
Perovskite-based Solar Panels
Glass-Backsheet Solar Panels
Glass-Glass Solar Panels
Building-Integrated Solar Panels.
Polymer-Based Solar Panels
Solar Roof Tiles
Solar Roof Shingles

Solar modules can last decades, with some degradation in performance over a module's lifetime. Also, solar modules that have been deployed on residential rooftops and other commercial and utility-scale applications for a number of years, may be decommissioned for a variety of reasons.

For example, (residential, commercial, utility) users of solar panels may desire to exchange their modules for newer, higher performing modules in order to maximize the amount of energy obtained from a solar array.

As more solar modules reach the end of their useful lives and/or are relinquished by their owners, it is desirable to recover valuable materials in the panels and avoid their being wasted by disposal in a landfill.

Once it is determined that a solar module is no longer useful to its owner, e.g.:
the module has reached the end of its current deployment due to non- or underperformance,
the module has been damaged in transit, or
for other (e.g., economic) reasons, in order to avoid discarding the module into a landfill, the module may be recycled.

Such recycling may employ one or more of the following processes, alone or in various combinations and sequences.
cleaning;
inspection to determine reusability;
testing;
remove cabling;
remove frames surrounding the panel and/or junction boxes (either manually, or e.g., using an automated deframing machine).
transparent front layers and potentially other layers (e.g., the backsheet) may be removed using a delamination process.

Remaining layers (of, e.g., a laminate) may be shredded. Shredded materials can be separated using one or more processes in order to extract various possible reusable materials therefrom (e.g., valuable commodity metals such as silicon, silver, and/or copper).

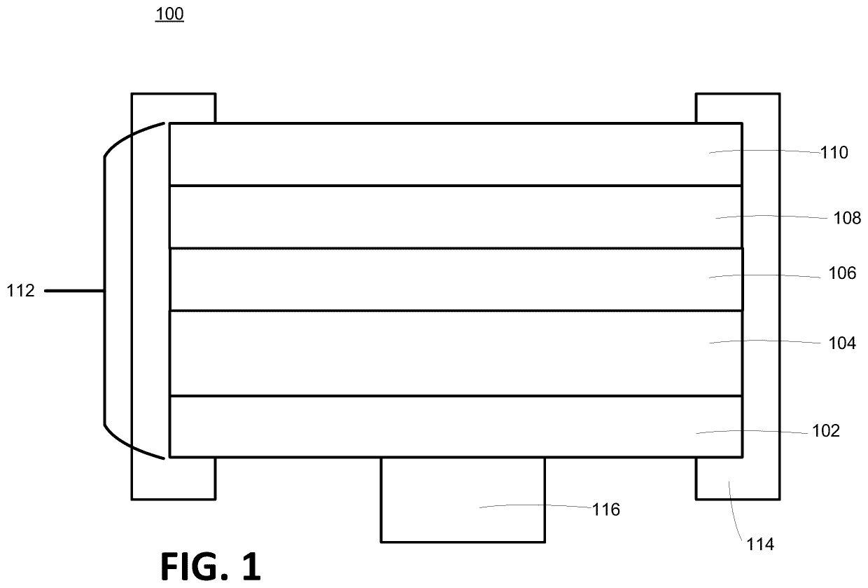

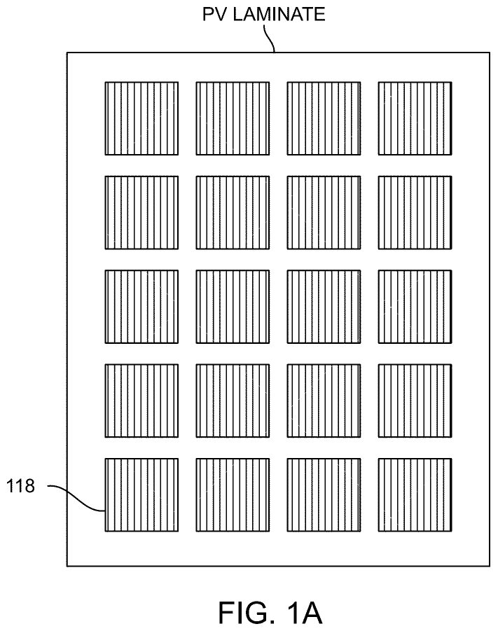

Embodiments relate to various techniques that may be employed, alone or in combination, for the recycling of solar modules. FIG. 1 shows a cross-sectional view of a monofacial solar module according to an example.

The PV module 100 is made of different layers assembled into the structure shown in FIG. 1. These layers of FIG. 1 are not drawn to scale.

The layers of FIG. 1 can be simplified as:
substrate (backsheet) 102,
back encapsulant 104, e.g., Ethylene-vinyl acetate (EVA), silicone, Polyvinyl butyral (PVB), IONOMER,
solar cell 106 comprising PV material (including, e.g., but not limited to: doped single crystal, polycrystalline, or amorphous silicon, Group III-V materials) and metallization,
front encapsulant 108,
transparent front cover sheet 110 (e.g., typically glass).
   This grouping of layers is referred to as a laminate 112.

It is further noted that bifacial modules also exist. Such bifacial modules may exhibit a structure similar to that of FIG. 1, but have a transparent (e.g., glass) layer instead of a backsheet layer. This allows (e.g., reflected) light to enter the module from the back.

The laminate in FIG. 1 is surrounded by a frame 114. The frame may comprise a stiff metal such as aluminum. Alternatively, a frame material may be plastic, comprising e.g., polycarbonate.

A junction box 116 is also part of the module. The junction box may be potted (more common in newer models) or non-potted (more common in older models). In a the potted PV junction box, the foils coming out of the solar panel are soldered to the diodes in the junction box, and the junction box is potted or filled with a type of sticky material to allow thermal transfer of heat to keep the solder joint in place and prevent it from falling. Fabrication may take longer but creates a better seal.

In the non-potted PV junction box, a clamping mechanism is used to attach the foil to the wires in the junction box. This can involve a faster assembly, but may not be as robust. A module having a potted junction box may be more amenable to recycling or refurbishment.

FIG. 1A shows a simplified overhead view of the laminate of a solar module, lacking the frame and the top transparent sheet. FIG. 1A shows solar cells including patterned metallization 118, which may comprise, e.g., a valuable metal such as silver.

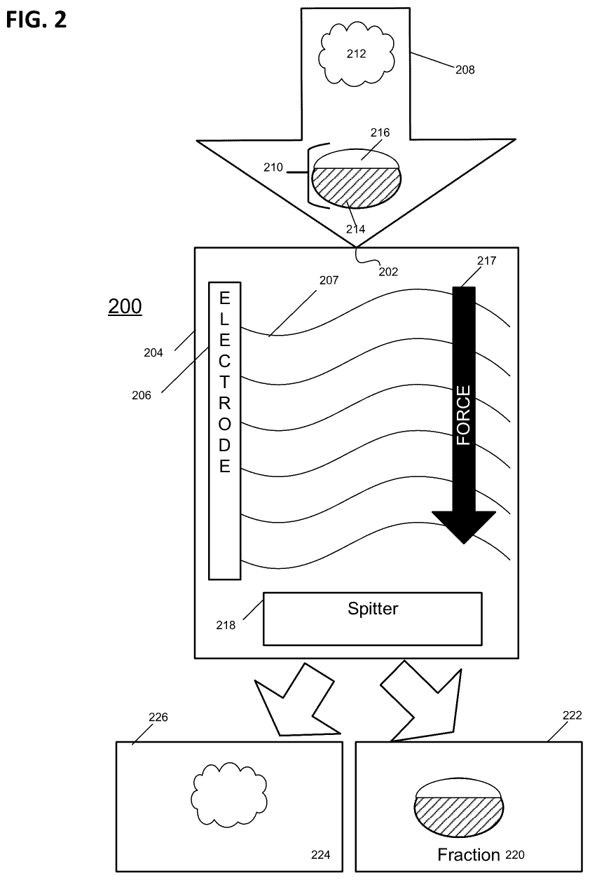

According to embodiments, separation of materials for recycling of a solar module, may be accomplished through the application of an electric field. FIG. 2 shows a simplified view of an embodiment of such a separation apparatus.

The apparatus 200 comprises an intake port 202 in communication with a chamber 204. At least one electrode 206 is configured to apply an electric field 207 to the chamber and materials present therein.

Input 208 to the apparatus comprises a mixture of materials from a solar module. This input may comprise a first particle 210 and a second particle 212. The mixture materials may be processed before entering the chamber 204 to achieve separation. The processing may include one or more of:
grinding,
shaking,
drying,
sieving,
slicing,
electrodynamic separation,
glass removal,
cutting,
shaving,
shredding,
application of fluid jet,
blasting,
application of ultrasound,
application of radiation,
application of solvents,
other.

Processing may serve to remove or alter various materials prior to the application of the electric field. Such material removal or alteration can increase the effectiveness of the separation process. Increased efficiency may be due to one or more factors.

For example, removing material from the input to the ES machine may result in a higher probability of a given particle touching the surface of the roller. If a particle happens to lay on top of another particle, it may not be fully grounded, and thus may not behave like a conductive particle. The outcome could be the particle not being properly separated or even being separated incorrectly (e.g., a silver particle being sent to a nonconductive output).

The smaller the ratio between the number of particles being separated and the area of the ground roller, the higher the probability of a successful and correct separation. Thus, processes such as glass removal, shredding and sieving of materials done prior to the ES separation, drying of the material, and/or collection of material by suction (e.g. dust collection) are beneficial to the later ES process.

Moreover, some particles can be small enough that they tend to stay in a suspension state (i.e., the force of gravity is not much greater than buoyancy forces or drag). Buoyancy forces can apply to very small particles (e.g., less the 1 micron), while drag may apply to bigger particles too.

According to specific embodiments, processing of materials that is performed upstream of ES separation may remove particles of a size of about 0.6 mm or less. This particle size also corresponds to fractions that can be obtained by sieving approaches.

The behavior of small particles in the ES equipment may not be the same as the particles that are larger. In particular, the path of (and thus final outcome) of such larger particles can be dependent on one or more of centripetal force, gravitational force, and/or electrostatic force within the ES separator. Therefore, it can be desirable to remove particles prior to the ES process through one or more of the above-referenced processes (such as sieving, suction, others).

Regarding glass material in particular, glass is a relatively fragile material whose fracture can generate dust. Thus, glass removal prior to the ES process separation can be particularly useful in removing smaller particles and enhancing the separation process.

The first particle comprises both a conductive portion 214 and a non-conductive portion 216. Examples of materials that may be present in the conductive portion can include but are not limited to:
metals—e.g., copper; silver; and/or aluminum.
semiconductors (e.g., solar grade silicon).

Examples of materials that may be present in the non-conductive portion can include but are not limited to:
polymers (e.g., encapsulant)
glass (e.g., solar grade optical glass).

Based upon the application of the electrical field, under the influence of a force 217 and a splitter 218, the contents of the input are separated into at least two fractions. A first fraction 220 comprises the first particle, comprising e.g., electrically conductive material. This first fraction is collected in a container 222 (e.g., a gaylord).

A second fraction 224 comprises the second particle. This second fraction is depleted in electrically conducting materials relative to the input, and may be collected in another container 226.

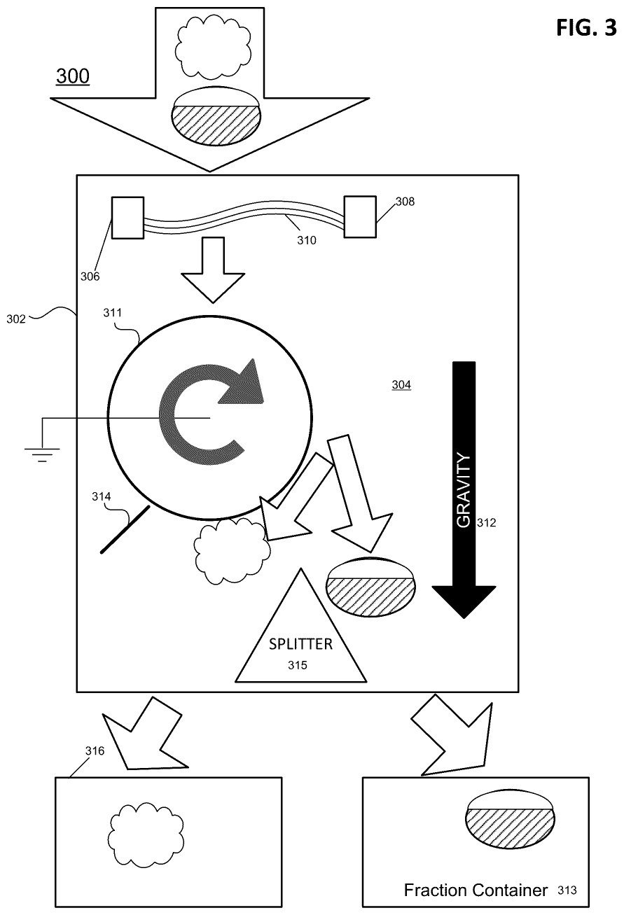

FIG. 3 shows a simplified view of one specific implementation of materials separation according to a particular embodiment. This apparatus 300 comprises a housing 302 enclosing a chamber 304 in which is present two electrodes 306 and 308.

An electrical field 310 is generated as between the two electrodes. A grounded, moving element 311 is disposed in the chamber. Here, this element is shown as a rotating roller, but in other embodiments it could comprise other components such as a belt.

As a result of the application of the electric field to the incoming particles, the electrically conductive materials are drawn into contact with the grounded roller. Their charge is neutralized by this contact, and then they fall under the influence of gravity 312 and the splitter 315, into the first container 313.

The electrically non-conducting materials contact the grounded roller and remain bound thereto by a coulombic attraction, for some period of time. The electrically non-conductive materials are removed from the roller by one or more of centripetal motion of the roller or a removal element 314. They are conveyed to the second container 316 by gravity.

Material separation according to embodiments, exploits differences in electrical conductivity of various materials. For materials present in a solar panel (e.g., glasses; polymers; semiconductors; metals) there are clear distinctions with respect to conductivity.

Among the materials contained in silicon solar panels, an approximate conductivity scale is listed below, in order of increasing conductivity:
glass;
polymers such as EVA, PVF, PVDF, PET, others;
silicon;
metals such as lead, tin, copper, silver, aluminum.

Even amongst the metals, there is difference in the electrical conductivity. Silver has the highest conductivity, followed by copper and the others.

By adjusting the electrical field intensity, it is possible to fine tune the separation of materials across a spectrum of material conductivities. The electric field can be adjusted by controlling the difference in electric potential (the voltage), based upon one or more of, e.g.:
distance between electrodes,
distance between the electrodes and the ground roller,
temperature, and
others.

By adjusting the voltage, one can bridge the band gap of a variety of materials. One practical example is that of silicon, which is considered a semiconductor with a known band gap between its conduction band and its electrical valance band.

Beyond certain voltages (˜1.1 eV), silicon behaves like a conductor and will therefore discharge into the grounded roller and not adhere thereto. By contrast, at lower voltages silicon will act as a non-conductor and will not discharge into the roller and will therefore adhere to it.

Similar approaches can be used for the various materials present in a solar module to achieve separation. Another example relates to separation of metals.

The voltage could be lowered to a point at which copper would act as a nonconductor and not discharge into the roller, adhering to it. Under that same voltage, silver would discharge and not adhere to the roller. This would separate silver and copper based upon the strength of the electric field that is applied.

Separation according to embodiments is not limited to solar modules comprising silicon. For example, thin film panels that use CdTe technology also include various materials having different electrical conductivities.

The CdTe semiconductor has a band gap of ˜1.4 eV. This band gap can be exploited to allow the CdTe to behave like a conductor or like a nonconductor material. Thus an electric field can be applied so that the copper from a CdTe panel behaves like a conductor material and does not adhere to the roller, while the CdTe behaves like a nonconductor and adheres to the roller. In this manner, the CdTe and copper can be separated.

Band gap and the electrical conductivity are both functions of temperature. Thus, the changing of temperature could also be exploited to selectively separate materials in the presence of an electric field.

Moreover, change in electrical conductivity as a function of temperature, behaves differently depending upon whether the material is typically a conductor, a nonconductor, or a semiconductor. Specifically, the conductivity of a conductor decreases with temperature, whilst the conductivity of a nonconductor and a semiconductor may increase.

Accordingly, this conductivity relation according to temperature may be leveraged to further distinguish the materials and create a higher voltage tolerance to target material over the other. For example, to separate silicon and silver, instead of solely relying on voltage adjustments one can decrease the temperature so that the conductivity of silver increases and that of silicon decreases. This serves to enhance the difference in conductivity between the two, rendering separation more effective.

The separation of glass may also depend upon temperature. In certain embodiments, glass can be separated at higher temperatures (e.g., about 110-140° C.). This temperature dependence for glass separation may be attributable to a reduction of humidity. The removal or reduction in the volume of glass input to the ES separation process may reduce a temperature dependence of separation.

It is noted that when water is present in the separation environment, it may change the behavior of some particles. For example, glass is a nonconductive material whose behavior changes with the presence of water.

This change is because the water molecules adhere to the surface of the glass particles, and because of the polar nature of water molecules and its electrical conductivity properties. Thus glass particles sized ˜0.3 mm or smaller, exhibit the behavior of conductive particles in the presence of water.

This effectively causes the glass to aggregate with other conductive materials (e.g. silver and copper) instead of aggregating with nonconductive materials (e.g. larger glass particles or polymers). Owing to this effect, it may be desirable to run the electrostatic separation of materials from solar panels without the presence of glass, in particular without the presence of small glass particles.

For example, if a solar panel has around >90 wt % of its original glass removed prior to the electric separation process, the process can proceed with higher effectiveness and may also eliminate or reduce a need to control the humidity of the storage environment and/or electric separation.

The ability to bypass such dryer processing through glass content reduction, may offer one or more of the following benefits.
i) Less energy is consumed—drying is a major part of the energy consumption of the whole process.
ii) Less time is consumed—drying is one of the slowest parts of the process.
iii) Higher throughput—drying is a limiting factor for the throughput.
iv) Less contamination potential—contamination during drying phase is avoided.
v) Remove the possibility of toxic emissions—drying has the potential of releasing toxic fumes if temperature is not properly controlled.
vi) More effective separation—achieving the optimum amount of drying may be exacting.

Glass removal may result in the removal of material in various amounts. In some embodiments, glass removal from a used solar module may remove around >90 wt % of its original glass. According to particular embodiments, glass removal may remove around >95 wt % of the original glass in the module. In specific embodiments, glass removal may remove around >96 wt % of the original glass in the module. Various embodiments may remove around >97 wt % of glass, around >98 wt % of glass, around >99 wt % of glass, or around 100 wt % of glass.

If the glass particles entering the electrostatic separation are greater than about 0.3 mm in diameter, the need for humidity control of the storage environment and/or the electric separation process may be reduced. Thus a sieving process prior to the electrostatic separation may be a successful way of increasing the effectiveness of the electrostatic separation process.

Density separation may be employed. Density separation can operate using air, nitrogen or other gases as a medium, or using water, oil or other liquids as a medium. Cyclone separation and/or particle filtering systems (dust collectors, air purifiers, etc.) could be employed.

In some embodiments, glass may comprise a large (70-80%) percentage by weight of the solar panel. So, by removing glass prior to the electrostatic process, the throughput of the process can be substantially increased.

Also, removal of glass allows the recovery of both the glass and the polymers. Otherwise, these could be aggregated into a single output co-mingling glass and polymers.

It is noted that materials originating from used solar panels may exhibit significantly different mechanical properties. Thus, when shredded/crushed/grinded/milled they end up as significantly different particle sizes. By contrast, like materials tend to aggregate around a single average size (e.g., copper pieces tend to be of similar size, while polymer pieces of another average similar size).

It has been identified that the following materials may exhibit the following trend of particle size, ordered from smaller to larger:
silver particles
silicon particles
glass particles;
copper particles;
polymer particles

Thus, sieving can be used as a way to concentrate specific materials prior to electric separation. Subsequent application of an electric field can allow for more purification.

As one possible example, sieving an incoming mixture of materials from a solar panel such that only particles smaller than 0.5 mm can pass, will concentrate the silver. That silver-enriched concentrate can then be exposed to electric field separation in order to obtain a fraction that is even more concentrated in silver (that may be or may not be subjected to further refinement).

The following table suggests some sizes for sieve openings that may be used to concentrate various materials.

| Material Concentrated | Sieve Opening Size (approximate) |
|---|---|
| Silver | <0.5 mm |
| Silicon | <1 mm and >0.5 mm |
| Copper | <2 mm and >1.18 mm |
| Lead | <2 mm and >1.18 mm |
| Tin | <2 mm and >1.18 mm |
| Glass | <3 mm and >2 mm |
| Polymers | >3 mm |

The effectiveness of material separation according to embodiments may be determined by a host of factors. One set of environmental factors that can influence separation, are temperature and humidity.

For example, it may be desirable that the temperature be between about −20 and 99° C., may be between about 40 and 90° C., or may be between about 85 and 87° C.

It may be desirable that the humidity be between about 0-70%, may be between about 30-60%, or may be between about 48-52.5%.

The character of the electric field may also influence the separation. It may be desirable that the applied potential be between about 0.5 eV and 50 kV, may be between about 1000V and 40 kV, or may be between about 30 kV and 35 kV.

In some embodiments, the electric field may be an electrostatic field. In other embodiments, the electric field may be other than electrostatic, for example as created by a moving electrode.

Embodiments may utilize electrokinetic separation. Electrokinetic separation separates materials based on their electrophoretic mobility and zeta potential. A fluid that includes charged particles is passed through a porous medium while an electric field is applied. The particles will migrate towards the oppositely charged electrode and can be separated based on their electrophoretic mobility.

In electrokinetic separation, a sample containing charged particles is placed in a capillary or microchannel, and an electric field is applied across the length of the channel. As the electric field is applied, the charged particles migrate at different rates towards the oppositely charged electrode, based on their charge properties. An electrokinetic separation process can be controlled with reference to one or more of:
the electric field strength,
the pH of the buffer solution,
the surface charge of the channel walls.

Where a grounded roller is used, the speed of rotation may affect the nature of the separation. It may be desirable that the rotation speed be between about 0.5 and 500 RPM, may be between about 5 and 50 RPM, or may be between about 25-28 RPM.

The nature of the input may also influence the separation. It may be desirable that the largest particle size of the input be between about 0.1 and 100 mm, may be between about 0.5 and 5 mm, or may be between about 2-4 mm.

It may be desirable that conductive material comprise by mass between about 5 and 100% of the weight of a particle, between about 50 and 90% by weight of a particle, or between about 72 and 75% by weight of a particle.

It may be desirable that the particles of the input fall within a relatively uniform range. Particle size may vary between about +/−500%, between about +/−100%, or between about +/−50%.

The input of the separation may be processed in order to achieve one or more desirable properties. Such processing can include but is not limited to one or more of the following, performed in any order:
glass removal;
grinding;
slicing;
cutting;
shaving;
shredding;
the application of fluid (e.g., gas or liquid) jet(s);
blasting with particles (e.g., silica, aluminum);
the application of ultrasound;
sieving;
shaking;
the application of radiation (e.g., UV; microwaves);
the application of solvents.

The nature of the force(s) that are present during the application of the electric field, may also determine the quality of the separation. Examples of such forces can include but are not limited to:
gravity
liquid flow
gas flow
resistance of a particle to travel through a particular medium (e.g., gas, air, liquid, water, partial vacuum).

Certain embodiments may employ suction for debris or collection of material of interest, such as polymers, silicon, metals, glass. Such collected material could be in the form of powder or fragments.

As mentioned above, particular embodiments may employ separation based upon rotating roller(s). Some embodiments may employ a single splitter for each roller, effectively separating the mixture into two fractions.

In some embodiments an electrostatic separator may have two splitters, and operates to separate the incoming mixture into three fractions: mostly conductive, mostly non-conductive, and a third fraction having mediate properties. Particular embodiments may simplify such a design by combining the mediate and the non-conductive fractions to result in only two fractions (e.g., per-stage). Such an electrostatic tool intakes the mixture and separates the conductive metals from the non-conductive remaining material into two different streams. The conductive materials may emerge through multiple outputs of the tool that can be chuted or conveyed to (e.g., 1M high) gaylords.

Particular embodiments could employ a cascade effect. There, non-conducting particles from one roller fall into the second roller. Four or even more consecutive rollers could be deployed in series to achieve desired separation of materials of interest.

The location of ionizing electrodes could be precisely positioned to accommodate mixtures having various properties. Electrode position can influence, amongst others, the voltage (varies with the distance squared) and the efficiency in charging the particles.

A separator may be made taller, thereby allowing for a gaylord to be placed underneath.

Heating elements (e.g., incandescent lamps) may be positioned inside the equipment. This can desirably increase the temperature and humidity control over the separation. Such heating elements can include an on/off control button. Humidity sensors inside the equipment may allow for automatic switching of lamps.

Dimensions of various parts of the machine (e.g., vibratory shelves) may be designed to avoid clogging. Shelves can also include moveable wipers to avoid clogging.

It is not required that the output of the separator be positioned at the bottom. Some embodiments could rotate the input hopper by 90 degrees so that output is to the sides of equipment. Chute(s) could be placed to the side of the equipment instead of at the bottom

In particular embodiments, the diameter of the roller may be 12′. The roller width could be up to about 60″, with corresponding attraction and ionizing electrodes. The use of such a wider roller and electrodes can increase surface area and the rate of throughput.

Various embodiments may include one or more of the following features.

Jigs must be provided to avoid reaching into the tool's process area to remove any part of a panel or pieces of a panel or provide safe contact with parts inside the tool (e.g., anti-static bars to ground tool parts safely).

Sufficient distance between the non-conductive output chute and the next vibratory shelf may be provided so as to avoid clogging of PV materials inside the machine.

Heating elements (e.g., incandescent lamps) may be disposed inside the machine to increase the temperature and provide humidity control of the process. Embodiments may allow measuring the internal humidity level on the PV intake region and stages of separation continuously during operation. Embodiments may have automated logic control system to maintain humidity within a certain range (e.g., under the 40% and 50% range).

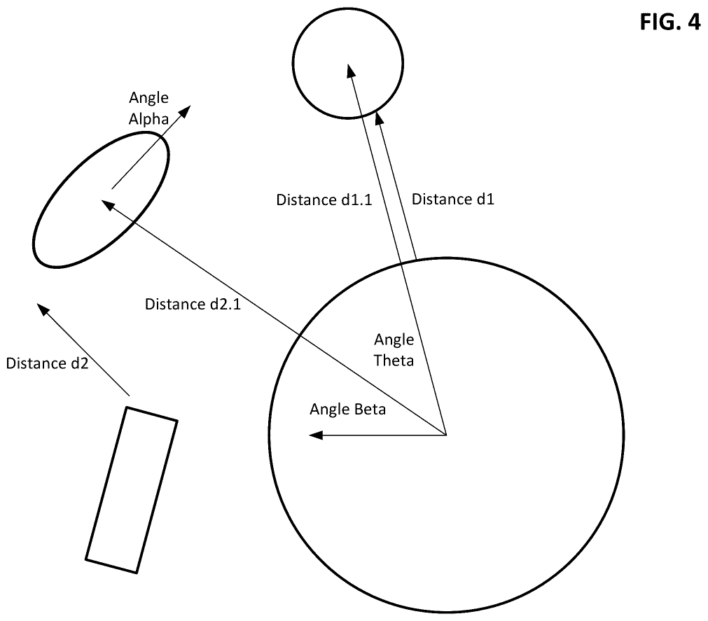

According to a particular embodiment utilizing a grounded roller, internal positioning electrodes (distance and angle) dispositive reaches at minimum, the following parameters shown in FIG. 4.

| | | |
|---|---|---|
| Angle beta | 10 | degrees |
| Angle theta | 46 | degrees |
| Angle alpha | 31 | degrees |
| Distance d1 | 5.5 | cm |
| Distance d1.1 | 23.3 | cm |
| Distance d2 | 10.2 | cm |
| Distance d2.2 | 31.5 | cm |

Embodiments may afford visual markers on the positioning electrode sets to provide an easy identification and allow production positioning without necessarily having to access the interior of the tool.

Embodiments may feature a moving wiper and/or a roller with spikes mechanism at the hopper of shelf section(s) to avoid clogging inside the machine.

The orientation of the input hopper may be rotated 90° to allow output at side(s) of the equipment. An output chute may be to the side rather than the bottom of the equipment, as the height of the tool may make bottom collection difficult.

Embodiments may position a sliding door that allows closing of the entrance. This may be useful where no dust collection is needed.
Clause 1A. A method comprising:
processing a used solar module to form a mixture comprising a first particle including a conductive material, and a second particle including a non-conductive material;
subjecting the mixture to a force in the presence of an electric field having a first difference in potential; and separating the first particle from the mixture.
Clause 2A. A method as in Clause 1A wherein the conductive material comprises between about 66%-100% by mass of the first particle.
Clause 3A. A method as in any of Clauses 1A or 2A wherein the force comprises gravity.
Clause 4A. A method as in Clause 3A wherein the gravity is opposed by a resistance of the first particle moving through a medium.
Clause 5A. A method as in Clause 4A wherein the medium comprises air.
Clause 6A. A method as in any of Clauses 1A, 2A, 3A, 4A, or 5A wherein the processing comprises sieving to remove particles having a diameter of about 3 mm or larger.
Clause 7A. A method as in any of Clauses 1A, 2A, 3A, 4A, 5A, or 6A wherein the processing further comprises drying the mixture.
Clause 8A. A method as in any of Clauses 1A, 2A, 3A, 4A, 5A, 6A, or 7A wherein the processing comprises removing glass from the mixture.
Clause 9A. A method as in any of Clauses 1A, 2A, 3A, 4A, 5A, 6A, 7A, or 8A wherein the first particle is present in a first fraction, the method further comprising:
subjecting the first fraction to the force in the presence of an electric field having a second difference in potential; and
collecting the first particle in a second fraction.
Clause 10A. A method as in Clause 9A wherein the first difference in potential is greater than the second difference in potential.
Clause 11A. A method as in Clause 9A wherein the first difference in potential is less than the second difference in potential.
Clause 12A. A method as in any of Clauses 1A, 2A, 3A, 4A, 5A, 6A, 7A, 8A, 9A, 10A, or 11A wherein the conductive material comprises a metal.
Clause 13A. A method as in Clause 12A wherein the metal is copper, silver, aluminum, and lead.
Clause 14A. A method as in any of Clauses 1A, 2A, 3A, 4A, 5A, 6A, 7A, 8A, 9A, 10A, 11A, 12A, or 13A wherein the conductive material comprises silicon.
Clause 15A. A method as in any of Clauses 1A, 2A, 3A, 4A, 5A, 6A, 7A, 8A, 9A, 10A, 11A, 12A, 13A, or 14A wherein the nonconductive material comprises a polymer.
Clause 16A. A method as in any of Clauses 1A, 2A, 3A, 4A, 5A, 6A, 7A, 8A, 9A, 10A, 11A, 12A, 13A, 14A, or 15A wherein the nonconductive material comprises glass.
Clause 17A. A method as in any of Clauses 1A, 2A, 3A, 4A, 5A, 6A, 7A, 8A, 9A, 10A, 11A, 12A, 13A, 14A, 15A, or 16A wherein the second particle has a size greater than about 3 mm and the processing does not include drying.
Clause 18A. A method as in any of Clauses 1A, 2A, 3A, 4A, 5A, 6A, 7A, 8A, 9A, 10A, 11A, 12A, 13A, 14A, 15A, 16A, or 17A wherein the processing comprises one or more of grinding, shaking, drying, sieving, slicing, electrostatic separation, electrokinetic separation, electrodynamic separation, glass removal, cutting, shaving, shredding, application of fluid jet, blasting, application of ultrasound, application of radiation, and application of solvents.
Clause 19A. A method as in any of Clauses 1A, 2A, 3A, 4A, 5A, 6A, 7A, 8A, 9A, 10A, 11A, 12A, 13A, 14A, 15A, 16A, 17A, or 18A wherein the separating comprises electrostatic separation.
Clause 20A. A method as in any of Clauses 1A, 2A, 3A, 4A, 5A, 6A, 7A, 8A, 9A, 10A, 11A, 12A, 13A, 14A, 15A, 16A, 17A, 18A, or 19A wherein the first particle contacts a grounded roller.

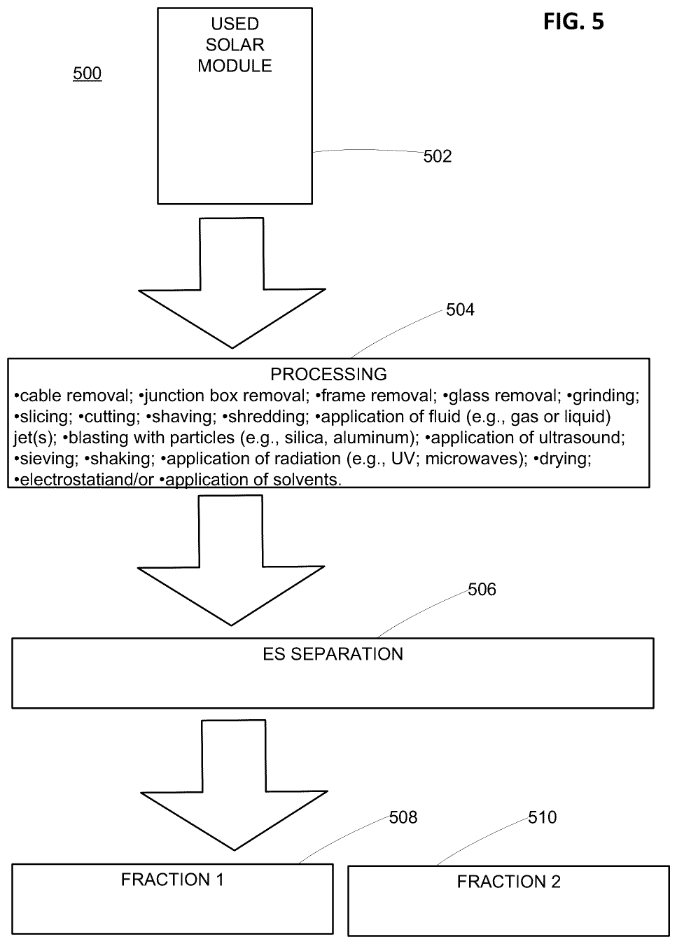

FIG. 5 shows a simplified flow diagram of processing of a used solar module for recycling, according to an embodiment. At 502 a used solar module is received.

At 504, the used solar module is subject to processing. Such processing can involve one or more of the specific actions listed, performed in any order, once or multiple times.

At 506, the output of the processing is input for electrostatic processing. Such ES processing can be in single or multiple stages.

The output of the ES processing can take the form of at least two fractions, 508 and 510. The content of the fractions may differ in terms of their electrical conductivities.

It is emphasized that the above approaches may be utilized alone, or in various combinations.

What is claimed is:

1. A method comprising:
processing a used solar module by glass removal of around greater than 90 wt % to form a mixture comprising a first particle including a conductive material, and a second particle including a non-conductive material;
subjecting the mixture to a force in the presence of an electric field having a first difference in potential; and
separating the first particle from the mixture.

2. A method as in claim 1 wherein the conductive material comprises between about 66%-100% by mass of the first particle.

3. A method as in claim 1 wherein the force comprises gravity.

4. A method as in claim 3 wherein the gravity is opposed by a resistance of the first particle moving through a medium.

5. A method as in claim 4 wherein the medium comprises air.

6. A method as in claim 1 wherein the processing comprises glass removal of around greater than 95 wt %.

7. A method as in claim 1 wherein the processing comprises glass removal of 100 wt %.

8. A method as in claim 1 wherein the processing comprises slicing.

9. A method as in claim 1 wherein the first particle is present in a first fraction, the method further comprising:
subjecting the first fraction to the force in the presence of an electric field having a second difference in potential; and
collecting the first particle in a second fraction.

10. A method as in claim 9 wherein the first difference in potential is greater than the second difference in potential.

11. A method as in claim 9 wherein the first difference in potential is less than the second difference in potential.

12. A method as in claim 9 wherein the conductive material comprises a metal.

13. A method as in claim 12 wherein the metal is copper, silver, aluminum, and lead.

14. A method as in claim 9 wherein the conductive material comprises silicon.

15. A method as in claim 12 wherein the nonconductive material comprises a polymer.

16. A method as in claim 1 wherein the nonconductive material comprises glass.

17. A method as in claim 16 wherein the second particle has a size greater than about 3 mm and the processing does not include drying.

18. A method as in claim 1 wherein the processing comprises one or more of grinding, shaking, drying, sieving, slicing, electrostatic separation, electrokinetic separation, electrodynamic separation, glass removal, cutting, shaving, shredding, application of fluid jet, blasting, application of ultrasound, application of radiation, and application of solvents.

19. A method as in claim 1 wherein the separating comprises electrostatic separation.

20. A method as in claim 19 wherein the first particle contacts a grounded roller.
